(19) United States
(12) Patent Application Publication
(10) Pub. No.: US 2006/0253407 A1
(43) Pub. Date: Nov. 9, 2006

(54) Monitoring system for an evaporative credit program

(76) Inventors: Loy A. Waddell, Fort Worth, TX (US); Mark A. Lewis, Little Rock, AR (US)

Correspondence Address: PATTON BOGGS, L.L.P., 2001 ROSS AVENUE, SUITE 3000, DALLAS, TX, 75201, US

(21) Appl. No.: 11/152,730

(22) Filed: Jun. 14, 2005

Related U.S. Application Data
(60) Provisional application No. 60/680,788, filed on May 14, 2005.

(51) Int. Cl. G01R 21/133

(52) U.S. Cl. 705/412

(57) ABSTRACT

A method of monitoring an evaporative credit program is provided in which a water meter reading of a utility service customer is received. An actual compliance index is determined based on the water meter reading. The actual compliance index is then compared to a desired compliance index to determine whether the utility service customer is compliant with the evaporative credit program. Compliance or non-compliance is then reported.

### BACKGROUND OF THE INVENTION

1. Field of the Invention

The present invention relates generally to utility service credit programs and in particular to a monitoring system for an evaporative credit program.

2. Description of Related Art

Utility service providers offer services to residential, retail, commercial, and industrial customers within and sometimes outside the physical boundaries of a municipality. In some cases, it is the municipality itself that is the utility service provider. In other cases, the municipality contracts with another entity to act as the utility service provider. One of the primary services offered by utility service providers is water service, which may be used by customers for a variety of purposes, some of which may include drinking, bathing, lawn watering, and cleaning. Water is typically sold according to the volume that is used by a customer. The water volume consumed by a customer is measured by a meter placed at the customer's residence, business, or other location of consumption. Sewage service is also sold to customers and is typically based on the volume of water that is sold to the customer. It is assumed that the water provided to the customer is ultimately returned to the municipality's sewage system.

Many utility service providers award credits to customers with evaporative cooling systems based on the volume of evaporated water used by the cooling system. Since evaporated water does not return to the municipality's sewage system, it is only fair that the customer not be charged for evaporated water. Although evaporative credit programs provide an equitable process to account for evaporation, evaporation is often overstated by customers due to problems with the customer's evaporative cooling system or dishonesty on the part of the customer. Studies suggest that millions of dollars of evaporation credits are wrongfully given each year to customers whose evaporation volumes are not as high as stated. Further, evaporation credits are sometimes underreported or lost by utility service providers, resulting in an economic loss to utility service customers.

### SUMMARY OF THE INVENTION

The problems presented by existing evaporation credit programs are solved by the systems and methods of the present invention. An evaporative credit monitoring system is provided in accordance with the principles of the present invention. The system includes a compliance server that receives water meter readings of a utility service customer and determines an actual compliance index based on the water meter readings. A storage medium may be provided and may store a desired compliance index. The actual compliance index is compared to the desired compliance index by a processor to determine at least one of utility service customer compliance with an evaporative credit program and a conservation opportunity for the utility service customer.

Also in accordance with the principles of the present invention, a method of monitoring an evaporative credit program is provided. A water meter reading is received from a utility service customer, and an actual compliance index for the utility service customer is determined based on the water meter reading. The actual compliance index is compared with a desired compliance index to determine at least one of utility service customer compliance with an evaporative credit program and a conservation opportunity for the utility service customer. The method further includes reporting the at least one of utility service customer compliance and the conservation opportunity for the utility service customer.

### BRIEF DESCRIPTION OF THE DRAWINGS

FIG. 1 illustrates a schematic view of an evaporative credit monitoring system according to an embodiment of the present invention;

FIG. 2 depicts a schematic view of an evaporative credit monitoring system according to an embodiment of the present invention, the system including a computer server and software program product configured to execute a method of monitoring an evaporative credit program;

FIG. 3 illustrates a flowchart showing communication between a utility service customer, an evaporation credit compliance monitor, and a utility service provider in accordance with a method of monitoring an evaporative credit program according to an embodiment of the present invention;

FIG. 4 depicts a flowchart showing communication between a utility service customer, an evaporation credit compliance monitor, and a utility service provider in accordance with a method of monitoring an evaporative credit program according to an embodiment of the present invention;

FIG. 5 illustrates a flowchart showing communication between a utility service customer, an evaporation credit compliance monitor, and a utility service provider in accordance with a method of monitoring an evaporative credit program according to an embodiment of the present invention;

FIG. 6 depicts a flowchart of a method of monitoring an evaporative credit program according to an embodiment of the present invention;

FIG. 7 illustrates a flowchart of a method of monitoring or managing an evaporative credit program according to an embodiment of the present invention; and

FIG. 8 depicts, in accordance with a method of managing an evaporative credit program according to an embodiment of the present invention, a method of determining whether a utility service customer is compliant with an evaporative credit program.

### DETAILED DESCRIPTION OF THE PREFERRED EMBODIMENT

In the following detailed description of the preferred embodiments, reference is made to the accompanying drawings that form a part hereof, and in which is shown by way of illustration specific preferred embodiments in which the invention may be practiced. These embodiments are described in sufficient detail to enable those skilled in the art to practice the invention, and it is understood that other embodiments may be utilized and that logical structural, mechanical, electrical, chemical, and other changes may be made without departing from the spirit or scope of the invention. To avoid detail not necessary to enable those skilled in the art to practice the invention, the description may omit certain information known to those skilled in the art. The following detailed description is, therefore, not to be taken in a limiting sense, and the scope of the present invention is defined only by the appended claims.

As used herein, the term “evaporative cooling system” refers to a system that derives at least a part of its cooling function from the evaporation of a fluid.

The term “municipality” refers herein to a governmental or quasi-governmental entity such as a city, a town, a district, a county, or a state.

The term “utility service provider” refers herein to a person or entity that provides utility services such as water, electricity, or natural gas to a utility service customer. The utility service provider may include without limitation a utility company or a municipality.

The term “utility service customer” refers herein to a person or entity that receives utility services from a utility service provider.

The term “compliance monitor” refers herein to a person or entity that monitors selected aspects of a utility service customer's participation in a utility service credit program such an evaporative credit program. A compliance monitor may include, without limitation, a third party other than the utility service provider or the utility service provider itself.

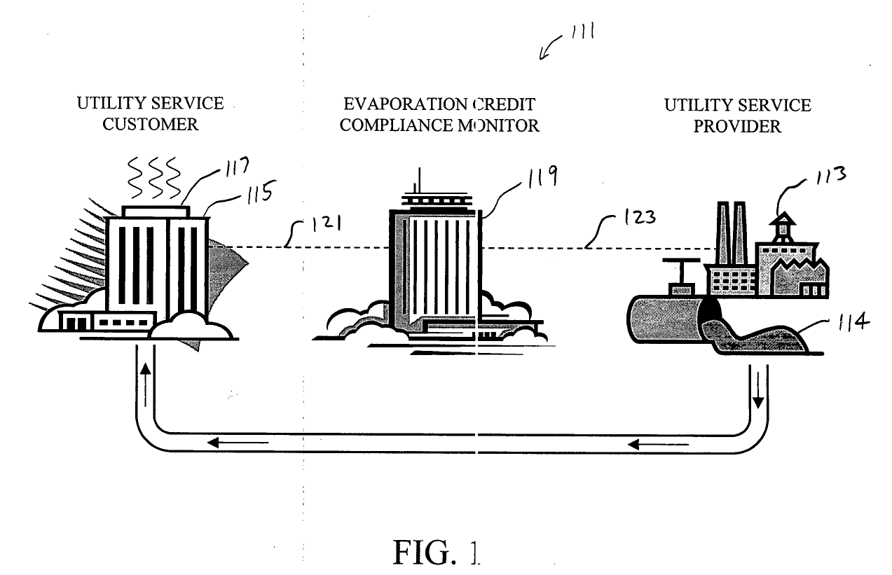

Referring to FIG. 1, an evaporative credit monitoring system 111 according to an embodiment of the present invention is schematically illustrated. The evaporative credit monitoring system 111 monitors an evaporative credit program offered by a utility service provider 113 such as a water utility service provider that provides utility services such as water 114 to a utility service customer 115. The evaporative credit program compensates the utility service customer 115 for excessive sewage charges when a portion of the water used by the utility service customer is evaporated through an evaporative cooling system 117. Utility service customers that have large amounts of air conditioned space often use evaporative cooling systems such as water cooling towers to dissipate heat. The evaporative cooling systems have large heat exchangers over which cooled water is passed. The water is cooled through evaporation, so new water must be supplied to the evaporative cooling systems to maintain a constant supply. Water is also bled from the evaporative cooling system to ensure that mineral and other particulate concentrations do not exceed desired levels. Excessive amounts of mineral or other particulates in the water will reduce the cooling efficiency of the evaporative cooling system and could even cause damage to the heat exchangers of the evaporative cooling system.

Since sewer charges for a utility service customer are typically determined by the amount of water consumed, the utility service customer may be overcharged for sewer services because evaporated water does not actually return to the sewage system. The evaporative credit program accounts for this disparity by allowing utility service customers with evaporative cooling systems to report the amount of evaporated water used by the evaporative cooling system. This evaporated water amount is subtracted from the utility service customer's total water consumption to determine the reduced sewage costs attributable to the utility service customer.

In order to determine the amount of evaporated water, a make-up, or inflow meter (not shown in FIG. 1) is positioned upstream of the evaporative cooling system 117 to measure the volume of water supplied to the evaporative cooling system 117. A bleed or outflow meter (not shown in FIG. 1) is positioned downstream of the evaporative cooling system 117 to measure the water exiting the evaporative cooling system and being dumped into the sewage system. In current practice, the volume of evaporated water is approximated by determining the amount of water bled from the evaporative cooling system during a given time period and subtracting this value from the amount of water supplied to the evaporative cooling system during the same time period. Although this calculation method can give a good approximation of the evaporated water volume, this calculation can in some instances lead to an overestimate of the evaporated water volume, thereby causing the utility service provider or municipality to award excessive evaporation credits. For example, some evaporative cooling systems have overflow drains that are directly connected to the sewage system and are not monitored by the bleed meter. If a utility service customer's evaporative cooling system is not functioning correctly, an excessive volume of water could pass through the overflow drain and bypass the bleed meter. This would effectively cause the “overflowed” water to appear as if it evaporated when it actually was released into the sewage system.

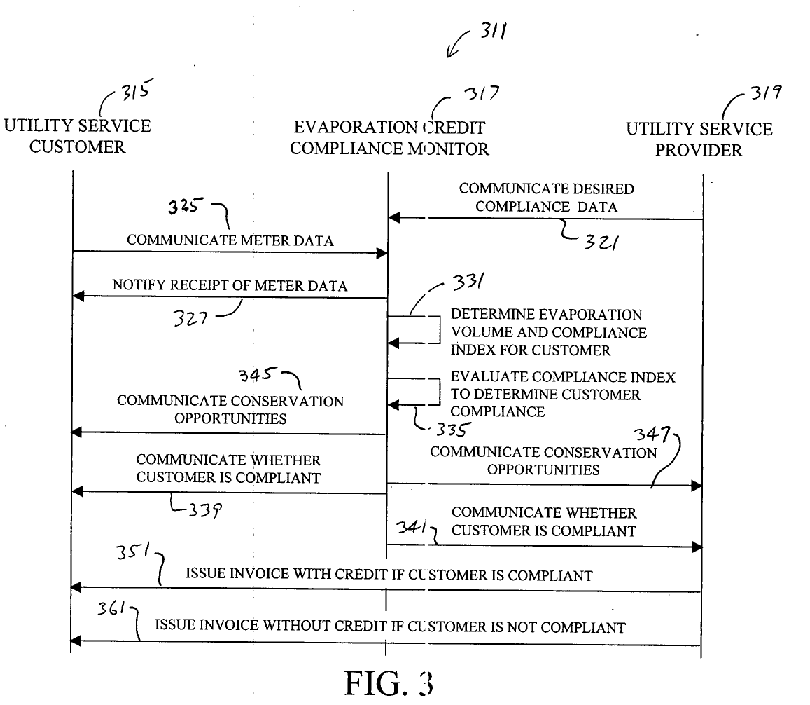

Referring still to FIG. 1, the evaporative credit monitoring system monitors utility service customer compliance with the evaporative credit program to ensure that the utility service customer does not obtain unwarranted evaporation credits. An evaporation credit compliance monitor 119 preferably serves as an intermediary between the utility service customer 115 and the utility service provider 113 to determine the compliance of the utility service customer 115 with the evaporation credit program and to alert the utility service customer and the utility service provider of conservation opportunities associated with the utility service customer's operation of the evaporative cooling system 117. Compliance with the evaporative credit program may be determined by calculating a compliance index for the utility service customer and comparing it with a desired compliance index selected by the utility service provider or municipality. This comparison also allows the evaporation credit compliance monitor 119 to identify potential conservation opportunities for the utility service customer. The calculation of the compliance index is described in more detail below with reference to FIG. 3. The function of the evaporation credit compliance monitor 119 may also be performed by either or both of the utility service customer 115 and the utility service provider 113 without exceeding the scope of the present invention.

Communication between the evaporation credit compliance monitor 119 and the utility service customer 115 may occur via communication connection 121, which may include without limitation a network connection, a wireless connection operating in the radio frequency range, the cellar frequency range, or any other frequency range, a telephone connection, a written communication, a physical inspection, or any other form of communication. Similarly, communication between the evaporation credit compliance monitor 119 and the utility service provider 113 may occur via communication connection 123, which may include without limitation a network connection, a wireless connection operating in the radio frequency range, the cellar frequency range, or any other frequency range, a telephone connection, a written communication, a physical inspection, or any other form of communication.

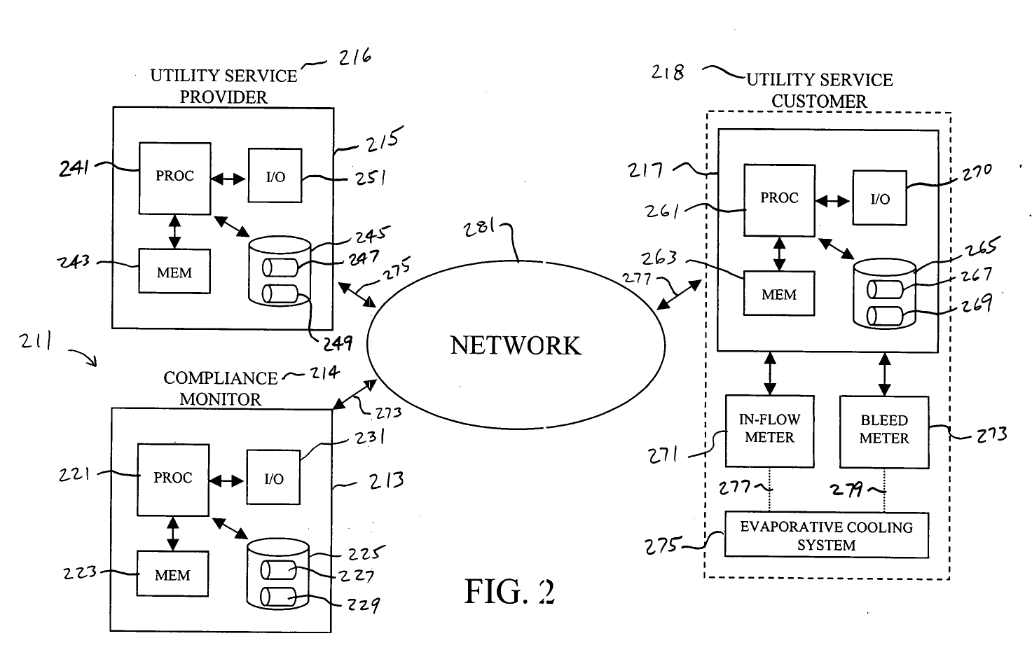

Referring to FIG. 2, an evaporative credit monitoring system 211 according to an embodiment of the present invention includes a compliance server 213 operable to communicate with a provider server 215 operated by a utility service provider 216 and a customer server 217 operated by a utility service customer 218. The compliance server 213 is preferably operated by a compliance monitor 214 but may be operated by the utility service provider 216. If the utility service provider 216 were to operate the compliance server 213, the provider server 215 may actually serve as the compliance server 213 to execute software as described in more detail below.

The compliance server 213 preferably includes a processor 221 operably connected to a memory medium 223 which could include RAM, ROM, or any other memory medium. The processor 221 may be composed of one or more processors in communication with each other. The compliance server 213 further includes a storage device 225 operably connected to the processor 221, the storage device 225 having at least one database 227 or data reservoir and a computer software program 229. The storage device could include a hard drive, magnetic media, optical media, or any other storage medium capable of storing data. The compliance server 213 further includes at least one input/output device 231 such as a keyboard, a mouse, or a display monitor.

Provider server 215 preferably includes a processor 241 operably connected to a memory medium 243 which could include RAM, ROM, or any other memory medium. The processor 241 may be composed of one or more processors in communication with each other. The provider server 215 further includes a storage device 245 operably connected to the processor 241, the storage device 245 having at least one database 247 or data reservoir and a computer software program 249. The storage device could include a hard drive, magnetic media, optical media, or any other storage medium capable of storing data. The provider server 215 further includes at least one input/output device 251 such as a keyboard, a mouse, or a display monitor.

The customer server 217 preferably includes a processor 261 operably connected to a memory medium 263 which could include RAM, ROM, or any other memory medium. The processor 261 may be composed of one or more processors in communication with each other. The customer server 217 further includes a storage device 265 operably connected to the processor 261, the storage device 265 having at least one database 267 or data reservoir and a computer software program 269. The storage device could include a hard drive, magnetic media, optical media, or any other storage medium capable of storing data. The customer server 217 further includes at least one input/output device 270 such as a keyboard, a mouse, or a display monitor.

In one embodiment, the customer server 217 may be connected to an inflow meter 271 and a bleed meter 273 of an evaporative cooling system 275. The inflow meter 271 measures a volumetric amount of water supplied to the evaporative cooling system 275. The bleed meter 271 measures a volumetric amount of water that is drained or bled from the evaporative cooling system 275. A communication connection 277, 279 may be connected to each of the inflow and bleed meters 271, 273 to provide communication with the customer server 217. The communication connection 277, 279 may include without limitation a network connection, a wireless connection operating in the radio frequency range, the cellar frequency range, or any other frequency range, a telephone connection, a written communication, a physical inspection, or any other form of communication. In some instances, the meter data for the inflow and bleed meters 271, 273 is physically read by either the utility service customer or the utility service provider. This data may then be entered into one of the servers 213, 215, 215 by using the input/output devices 231, 251, 270. In another example, the inflow and bleed meters 271 are capable of transmitting meter data wirelessly either to the customer server 217 or to the compliance server 213.

The processor 221 of compliance server 213 is configured to execute computer software 229 when loaded into memory medium 223 to perform a method of monitoring or managing an evaporative credit program according to an embodiment of the present invention. Similarly, processors 241 and 261 are configured to execute software 249 and 269, respectively. The methods performed by the software may include the methods discussed herein in reference to FIGS. 3-8.

The methods performed by computer software 229, 249, and 269 may be accomplished by communication between the compliance server 213, the provider server 215, and the customer server 217 over a network 281. Each server 213, 215, 217 includes a network connection 273, 275, 277 that enables communication with the network 281. Each of the network connections 273, 275, 277 may include an electronic connection, a wireless connection, a telephone connection, a letter, a report, or any form of connection or verbal or written communication.

Referring to FIG. 3, communications between a utility service customer 315, an evaporation credit compliance monitor 317, and a utility service provider 319 are illustrated in accordance with a method of monitoring an evaporative credit program 311 according to an embodiment of the present invention. In one embodiment, the servers 211, 215, and 217 (FIG. 2) executing software 229, 249, and 269, respectively, may be utilized to perform the communications and operations illustrated in FIG. 3. Preferably, the utility service provider communicates desired compliance data at step 321 to the evaporation credit compliance monitor 317. The desired compliance data represents a standard that the utility service provider requires the utility service customer to meet in order to qualify for evaporation credits. Although ultimately decided by the utility service provider 319, the evaporation credit compliance monitor 317 may be involved in helping the utility service provider 319 choose the desired compliance data, which is preferably in the form of a desired compliance index. Once the desired compliance index is chosen for a particular geographical region by the utility service provider 319, the desired compliance index is unlikely to change. For this reason, it is not necessary for the utility service provider 319 to communicate the desired compliance index to the evaporation credit compliance monitor 317 once the evaporation credit compliance monitor 317 stores the desired compliance index.

At step 325, the utility service customer 315 communicates meter data to the evaporation credit compliance monitor 317. Preferably, communication between the utility service customer 315 and the evaporation credit compliance monitor 317 is accomplished by having the utility service customer 315 log onto an Internet web site or other network associated with the evaporation credit compliance monitor 317. The utility service customer 315 then enters the meter data, thereby delivering the meter data to the evaporation credit compliance monitor 317 electronically. Alternatively, the meter data may be communicated to the evaporation credit compliance monitor 317 by a meter having a wireless connection to the evaporation credit compliance monitor 317. Still another communication method may include having a meter reader or other employee of the evaporation credit compliance monitor 317 or utility service provider 319 visit the utility service customer and physically read the meter data. The meter data may also be communicated by any other suitable means of communicating data.

In response, the evaporation compliance monitor notifies the utility service customer 315 that the meter data has been received at step 327. Meter data is received for both an inflow meter and a bleed meter operably connected to the evaporative cooling system. Since meter data is usually reported in terms of an absolute numerical value (as opposed to a differential numerical value), the meter data will typically be compared to a previous meter reading to determine the amount of water passing the meter during a given amount of time. For example, if the meter data (i.e. meter reading) at a first time is equal to 48,345 and the meter data at a second and later time is equal to 56,423, then the difference between the two values (8,078) represents the amount of water passing the meter between the first time and the second time. In most cases, the meter data is represented in terms of volume, but the meter data could also be represented in terms of mass, or other suitable units of measurement. After receiving meter data from the utility service customer, the evaporation credit compliance monitor may make the meter data and associated evaporation data accessible for viewing by the utility service customer or utility service provider over the Internet or another network.

After the meter data for the inflow and bleed meters is received and the volumetric amounts of water passing each meter have been determined, the evaporation credit compliance monitor 317 determines an actual compliance index (i.e. a actual compliance index) for the utility service customer at step 331 according to the following formula:

$$ComlianceIndex = \frac{VolumeConsumed}{VolumedBled} ,$$

where VolumeConsumed is the volume of water consumed by the evaporative cooling system during a given time period as indicated by the inflow meter volume, and VolumeBled is the amount of water drained from the evaporative cooling system during the given time period as indicated by the bleed meter volume.

It should be noted that the actual compliance index for a customer could be determined by alternative means. For example, compliance could be determined according to one of the following formulas:

$$ComlianceIndex = \frac{( VolumeConsumed - VolumedBled )}{VolumeConsumed} , or$$

$$ComlianceIndex = \frac{( VolumeConsumed - VolumedBled )}{VolumedBled} .$$

Preferably, the compliance determination involves a ratio between the amounts of water consumed, evaporated, or bled during a given time period. However, other compliance determination methods could be used, as long as the method of determining compliance is consistent with the method used to determine the standard for compliance (e.g. the desired compliance index).

The actual compliance index for the utility service customer is evaluated at step 335 by the evaporation credit compliance monitor to determine whether the utility service customer is compliant or non-compliant with the evaporation credit program. In one embodiment, this may be accomplished by comparing the actual compliance index to the desired compliance data previously received from the utility service provider. When the actual compliance index meets the standards represented by the desired compliance data, the utility service customer is compliant with the evaporation credit program and is therefore eligible to receive evaporation credits. If the actual compliance index is outside of the standards represented by the desired compliance data, then the actual compliance index is further evaluated to determine if conservation opportunities exist for the utility service customer.

In one particular example, a municipality decides that utility service customers should meet a desired compliance index of 5 in order to quality for evaporation credits. Over a one-month period, one utility service customer consumed 100,000 gallons of water as indicated by the inflow meter connected to the evaporative cooling system. During the same month, the bleed meter for the same customer reports that 20,000 gallons of water were bled from the evaporative cooling system and returned to the sewage system. The actual compliance index for this particular customer in this month is equal to 5, which is equal to the desired compliance index required by the municipality. The utility service customer in this particular case has met the requirements for participation in the evaporation credit program, which means that the utility service customer is eligible to receive credits based on the amount of water evaporated from the evaporative cooling system. In the present example, the utility service customer would only be charged for 20,000 gallons of water being returned to the sewage system. Alternatively, the utility service customer may be charged sewage for the entire 100,000 gallons, but then issued evaporation credits based on 80,000 gallons of evaporation.

In another example, another utility service customer has a one-month consumed volume of 60,000 gallons of water and a one-month bled volume of water equal to 20,000. The actual compliance index for this customer is equal to 3, which is less than the desired compliance index of 5 set by the municipality. In this particular case, the utility service customer is compliant with the evaporation credit program, but a conservation opportunity exists for the utility service customer due to the relatively high amount of water being bled from the evaporative cooling system. When only 60,000 gallons of water are consumed, a bleed amount of 20,000 indicates that the evaporative cooling system is not being operated efficiently. The conservation opportunity exists because the evaporative cooling system should be able to operate without bleeding such an excessive amount of water from the system.

In still another example, a utility service customer has a one-month consumed volume of 140,000 gallons of water and a one-month bled volume of water equal to 20,000. The actual compliance index for this customer is equal to 7, which is greater than the desired compliance index of 5 set by the municipality. In this particular case, the utility service customer is not compliant with the evaporation credit program because the high evaporation amount is not consistent with the high amount of water consumed. The numbers essentially indicate that 120,000 gallons of the 140,000 gallons of water supplied to the utility service customer was evaporated. In a geographical region with a desired compliance index of 5, evaporation rates at this level are not likely. Instead, the evaporation is falsely indicated as being high because of factors related to the operation of the evaporative cooling system or because of dishonesty on the part of the utility service customer. Sometimes an evaporative cooling system has overflow valves that are not monitored by the bleed meter. If the evaporative cooling system is not operating properly, overflow of water into the sewage system could occur without the water being recorded by the bleed meter. This may cause an extreme misrepresentation of the actual amount of water entering the sewage system, and under normal circumstances, would result in the utility service provider issuing excessive evaporation credits to the utility service customer.

Referring still to FIG. 3, after compliance or non-compliance of the utility service customer has been determined, the evaporation credit compliance monitor communicates at step 339 to the utility service customer and at step 341 to the utility service provider whether the utility service customer is compliant or non-compliant. If the determination of the compliance index for the utility service customer indicates conservation opportunities, the evaporation credit compliance monitor communicates these conservation opportunities to the utility service customer at step 345 and to the utility service provider at step 347.

If the utility service customer is compliant with the evaporative credit program, the utility service provider may issue an invoice with evaporation credits to the utility service customer 315 at step 351. The evaporation credits account for the evaporation that occurred in the evaporative cooling system by not charging the utility service customer 315 sewer charges for the evaporated water amount. Typically, the evaporation credits will be applied against water and sewer charges that the utility service customer is billed by the utility service provider. However, the evaporation credit could also be delivered to the utility service customer in the form of a refund check, a voucher for future discounts on utility services, or any other form of credit. It should be understood that the invoice may be issued by an entity other than the utility service provider 319.

If the utility service customer is not compliant with the evaporative credit program, the utility service provider may issue an invoice without evaporation credits at step 361. The invoice may point out that the utility service customer has failed to comply with the standards set for the evaporative credit program. In some instances, repeated non-compliance with the evaporative credit program by a utility service customer may result in future ineligibility to participate in the program, and this notification may also be included on the invoice. If the utility service client is repeatedly non-compliant, the utility service provider may request that the compliance monitor or another entity perform an on-site audit of the utility service customer's evaporative cooling system to determine potential areas of improving the operation of the evaporative cooling system.

Preferably, the issuance or denial of evaporation credits is absolute. In other words, if the utility service customer does not comply with the evaporative credit program, then no credits are issued. It is conceivable, however, that partial evaporation credits could be issued when a utility service customer does not comply with the evaporative credit program. For example, if the stated evaporation amounts for a utility service customer are much higher than expected in view of the desired compliance index, the utility service provider could use the desired compliance index to predict the amount of evaporation that should have occurred based on the utility service customer's total water consumption. Evaporation credits could then be issued for this predicted amount of evaporation.

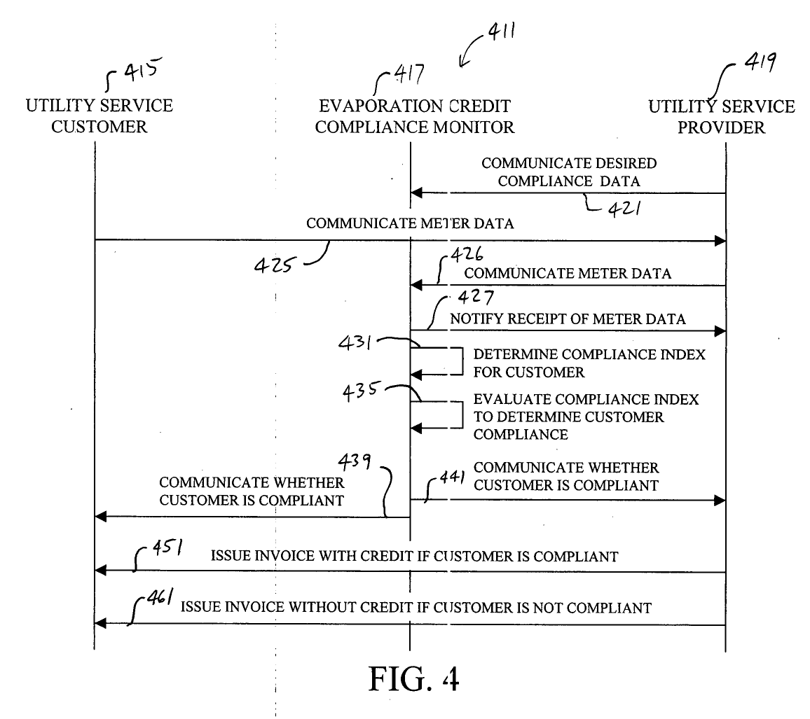

Referring now to FIG. 4, communications between a utility service customer 415, an evaporation credit compliance monitor 417, and a utility service provider 419 are illustrated in accordance with a method of monitoring an evaporative credit program 411 according to an embodiment of the present invention. In one embodiment, the servers 211, 215, and 217 (FIG. 2) executing software 229, 249, and 269, respectively, may be utilized to perform the communications and operations illustrated in FIG. 4. Preferably, the utility service provider communicates desired compliance data at step 421 to the evaporation credit compliance monitor 417. The desired compliance data represents a standard that the utility service provider will require the utility service customer to meet in order to qualify for evaporation credits. Although ultimately decided by the utility service provider 419, the evaporation credit compliance monitor 417 may be involved in helping the utility service provider 419 choose the desired compliance data, which is preferably in the form of a desired compliance index. Once the desired compliance index is chosen for a particular geographical region by the utility service provider 419, the desired compliance index is unlikely to change. For this reason, it is not necessary for the utility service provider 419 to communicate the desired compliance index to the evaporation credit compliance monitor 417 once the evaporation credit compliance monitor 417 stores the desired compliance index.

At step 425, the utility service customer 415 communicates meter data to the utility service provider 419. Communication between the utility service customer 415 and the utility service provider 419 could be accomplished by having a meter reader or other employee of the utility service provider 419 visit the utility service customer site and physically read the meter data. Alternatively, the utility service customer 415 may transmit the meter data to the utility service provider via the Internet, another network connection, or any other means of communication.

After receiving the meter data, the utility service provider 419 communicates the meter data at step 426 to the evaporation credit compliance monitor 417. In response, the evaporation compliance monitor 417 notifies the utility service provider 419 that the meter data has been received at step 427. Meter data is received for both an inflow meter and a bleed meter operably connected to the evaporative cooling system. Since meter data is usually reported in terms of an absolute numerical value (as opposed to a differential numerical value), the meter data will typically be compared to a previous meter reading to determine the amount of water passing the meter during a given amount of time. For example, if the meter data (i.e. meter reading) at a first time is equal to 48,345 and the meter data at a second and later time is equal to 56,423, then the difference between the two values (8,078) represents the amount of water passing the meter between the first time and the second time. In most cases, the meter data is represented in terms of volume, but the meter data could also be represented in terms of mass, or other suitable units of measurement. After receiving meter data, the evaporation credit compliance monitor may make the meter data and associated evaporation data accessible for viewing by the utility service customer or utility service provider over the Internet or another network.

After the meter data for the inflow and bleed meters is received and the volumetric amounts of water passing each meter have been determined, the evaporation credit compliance monitor 417 determines an actual compliance index (i.e. a actual compliance index) for the utility service customer at step 431 according to the following formula:

$$ComlianceIndex = \frac{VolumeConsumed}{VolumedBled} ,$$

where VolumeConsumed is the volume of water consumed by the evaporative cooling system during a given time period as indicated by the inflow meter volume, and VolumeBled is the amount of water drained from the evaporative cooling system during the given time period as indicated by the bleed meter volume.

It should be noted that the actual compliance index for a customer could be determined by alternative means. For example, compliance could be determined according to one of the following formulas:

$$ComlianceIndex = \frac{( VolumeConsumed - VolumedBled )}{VolumeConsumed} , or$$

$$ComlianceIndex = \frac{( VolumeConsumed - VolumedBled )}{VolumedBled} .$$

Preferably, the compliance determination involves a ratio between the amounts of water consumed, evaporated, or bled during a given time period. However, other compliance determination methods could be used, as long as the method of determining compliance is consistent with the method used to determine the standard for compliance (e.g. the desired compliance index).

The actual compliance index for the utility service customer is evaluated at 435 by the evaporation credit compliance monitor 417 to determine whether the utility service customer 415 is compliant or non-compliant with the evaporation credit program. Preferably, this is accomplished by comparing the actual compliance index to the desired compliance data previously received from the utility service provider 419. When the actual compliance index meets the standards represented by the desired compliance data, the utility service customer 415 is compliant with the evaporation credit program and is therefore eligible to receive evaporation credits. If the actual compliance index is outside of the standards represented by the desired compliance data, then the actual compliance index is further evaluated to determine if conservation opportunities exist for the utility service customer 415. The examples previously mentioned in reference to FIG. 3 for determining compliance are equally applicable to the method of FIG. 4.

Referring still to FIG. 4, after compliance or non-compliance of the utility service customer 415 has been determined, the evaporation credit compliance monitor 417 communicates at step 439 to the utility service customer 415 and at step 441 to the utility service provider whether the utility service customer is compliant or non-compliant. If the determination of the compliance index for the utility service customer indicates conservation opportunities, the evaporation credit compliance monitor 417 communicates these conservation opportunities to the utility service customer 415 and to the utility service provider 419.

If the utility service customer 415 is compliant with the evaporative credit program, the utility service provider 419 may issue an invoice with evaporation credits to the utility service customer at step 451. The evaporation credits account for the evaporation that occurred in the evaporative cooling system by not charging the utility service customer 415 sewer charges for the evaporated water amount. Typically, the evaporation credits will be applied against water and sewer charges that the utility service customer 415 is billed by the utility service provider 419. However, the evaporation credit could also be delivered to the utility service customer 415 in the form of a refund check, a voucher for future discounts on utility services, or any other form of credit. It should be understood that the invoice may be issued by an entity other than the utility service provider 419.

If the utility service customer 415 is not compliant with the evaporative credit program, the utility service provider 419 may issue an invoice without evaporation credits at step 461. The invoice may point out that the utility service customer 415 has failed to comply with the standards set for the evaporative credit program. In some instances, repeated non-compliance with the evaporative credit program by a utility service customer 415 may result in future ineligibility to participate in the program, and this notification may also be included on the invoice. If the utility service client is repeatedly non-compliant, the utility service provider may request that the compliance monitor or another entity perform an on-site audit of the utility service customer's evaporative cooling system to determine potential areas of improving the operation of the evaporative cooling system.

Preferably, the issuance or denial of evaporation credits is absolute. In other words, if the utility service customer 415 does not comply with the evaporative credit program, then no credits are issued. It is conceivable, however, that partial evaporation credits could be issued when a utility service customer 415 does not comply with the evaporative credit program. For example, if the stated evaporation amounts for a utility service customer 415 are much higher than expected in view of the desired compliance index, the utility service provider 419 could use the desired compliance index to predict the amount of evaporation that should have occurred based on the utility service customer's total water consumption. Evaporation credits could then be issued for this predicted amount of evaporation.

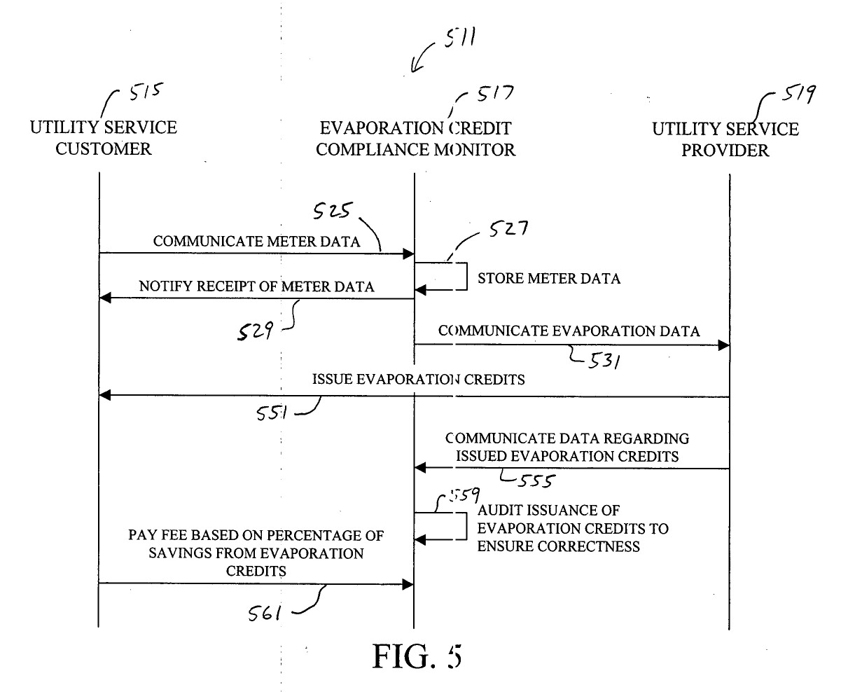

Referring now to FIG. 5, communications between a utility service customer 515, an evaporation credit compliance monitor 517, and a utility service provider 519 are illustrated in accordance with a method of monitoring an evaporative credit program 511 according to an embodiment of the present invention. In one embodiment, the servers 211, 215, and 217 (FIG. 2) executing software 229, 249, and 269, respectively, may be utilized to perform the communications and operations illustrated in FIG. 5. Evaporation credit compliance monitor preferably serves as an intermediary between the utility service customer 515 and the utility service provider 519 to ensure the utility service customers evaporation data is accurately reported in exchange for a percentage of the savings enjoyed by the utility service customer as a result of the evaporation credits.

At step 525, the utility service customer 515 communicates meter data to the evaporation credit compliance monitor 517. Preferably, communication between the utility service customer 515 and the evaporation credit compliance monitor 517 is accomplished by installing a meter capable of wireless transmission at the evaporative cooling system. The meter may include a wireless transmitter or may be connected to a wireless modem or other wireless transmitter to allow wireless transmission of meter data to the evaporation credit compliance monitor 517. Alternatively, communication of meter data may be accomplished by having the utility service customer 515 log onto an Internet web site or other network associated with the evaporation credit compliance monitor 517. The utility service customer 515 then enters the meter data, thereby delivering the meter data to the evaporation credit compliance monitor 517 electronically. Alternatively, the meter data may be communicated to the evaporation credit compliance monitor 517 by having a meter reader or other employee of the evaporation credit compliance monitor 517 or utility service provider 519 visit the utility service customer and physically read the meter data. The meter data may also be communicated by any other suitable means of communicating data.

After receiving the meter data, the evaporation compliance monitor 517 may store the meter data at step 527 and notify the utility service provider 519 that the meter data has been received at step 529.

Meter data is received for both an inflow meter and a bleed meter operably connected to the evaporative cooling system. Since meter data is usually reported in terms of an absolute numerical value (as opposed to a differential numerical value), the meter data may be compared to a previous meter reading to determine the amount of water passing the meter during a given amount of time. For example, if the meter data (i.e. meter reading) at a first time is equal to 48,345 and the meter data at a second and later time is equal to 56,423, then the difference between the two values (8,078) represents the amount of water passing the meter between the first time and the second time. In most cases, the meter data is represented in terms of volume, but the meter data could also be represented in terms of mass, or other suitable units of measurement.

After the meter data for the inflow and bleed meters is received, the volumetric amounts of water flowing through each meter for the given time period are calculated. The evaporated water volume is then determined according to the following formula:
EvapVolume=VolumeConsumed−VolumeBled,

where VolumeConsumed is the volume of water consumed by the evaporative cooling system during a given time period as indicated by the inflow meter volume, and VolumeBled is the amount of water drained from the evaporative cooling system during the given time period as indicated by the bleed meter volume. The evaporated water volume is communicated to the utility service provider at step 531 to facilitate the issuance of evaporation credits to the utility service customer. After receiving meter data from the utility service customer, the evaporation credit compliance monitor may make the meter data and associated evaporation data accessible for viewing by the utility service customer or utility service provider over the Internet or another network.

Based on the evaporation data received from the evaporation compliance monitor 517, the utility service provider 519 issues an invoice with evaporation credits to the utility service customer at step 551. The evaporation credits account for the evaporation that occurred in the evaporative cooling system by not charging the utility service customer 515 sewer charges for the evaporated water amount. Typically, the evaporation credits will be applied against water and sewer charges that the utility service customer 515 is billed by the utility service provider 519. However, the evaporation credit could also be delivered to the utility service customer 515 in the form of a refund check, a voucher for future discounts on utility services, or any other form of credit. It should be understood that the invoice may be issued by an entity other than the utility service provider 519. As a result of the evaporation credits, the utility service provider 519 obtains savings that would not otherwise be obtained absent participation in the evaporative credit program.

The utility service provider 519 communicates to the evaporation credit compliance monitor 517 at 555 data regarding the evaporation credits issued to the utility service customer 515. At 559, the evaporation credit compliance monitor 517 audits the evaporation credit data to ensure that the utility service customer 515 was properly credited. In exchange for the service of reporting the evaporation data and auditing the evaporation credits issued, the utility service customer 515 pays a fee at 561 to the evaporation credit compliance monitor 517 in return for the savings obtained by the utility service customer 515. This fee may be paid as a percentage of the savings enjoyed by the utility service customer, may be a fixed fee, or may be any other type of fee arrangement.

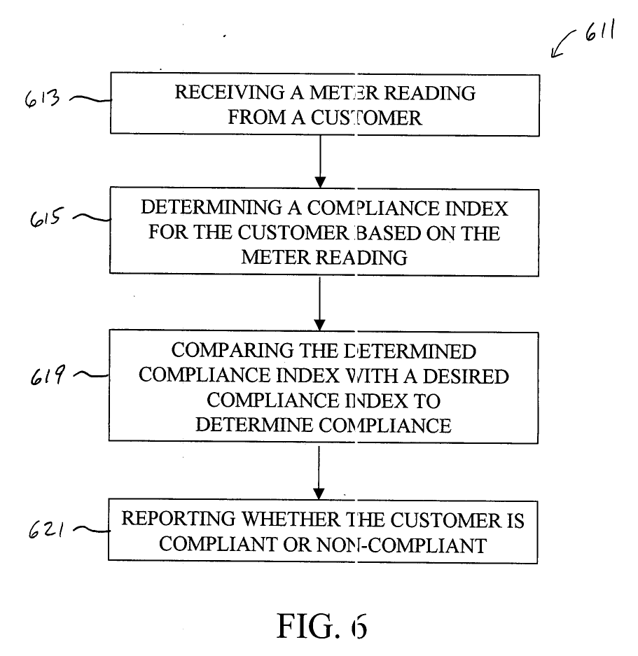

Referring to FIG. 6, a method 611 for monitoring an evaporative credit program according to an embodiment of the present invention includes a step 613 of receiving a meter reading from a utility service customer. An actual compliance index is determined for the utility service customer at step 615 based on the meter reading. At step 619, the actual compliance index is compared to the desired compliance index to determine compliance of the utility service customer with an evaporative credit program. The compliance or non-compliance of the utility service customer is reported at step 621.

In one embodiment, steps 613, 615, 619, and 621 of method 611 may be executed by software 229, 249, and 269 associated with servers 211, 215, and 217 (FIG. 2). The method 611 may further be performed in accordance with the communication flowcharts illustrated in FIGS. 3 and 4. For example, the determination of an actual compliance index may be accomplished using the following formula:

$$ComlianceIndex = \frac{VolumeConsumed}{VolumedBled} ,$$

where VolumeConsumed is the volume of water consumed by the evaporative cooling system during a given time period as indicated by the inflow meter volume, and VolumeBled is the amount of water drained from the evaporative cooling system during the given time period as indicated by the bleed meter volume.

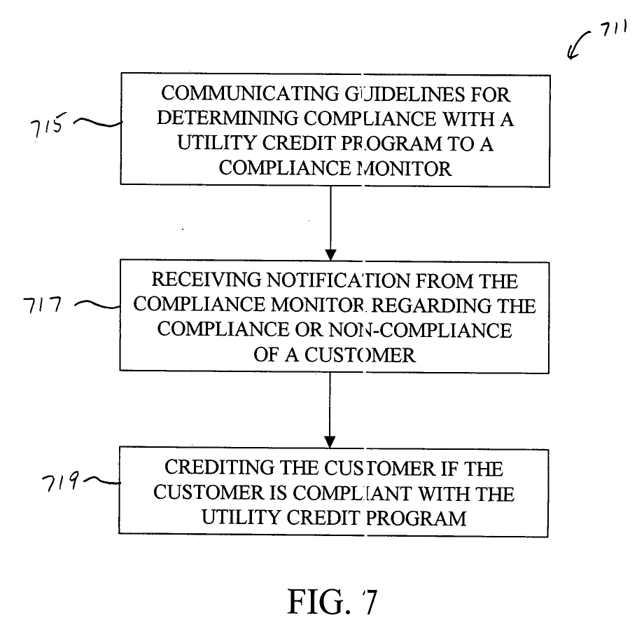

Referring to FIG. 7, a method 711 for managing an evaporative credit program according to an embodiment of the present invention includes a step 715 of communicating guidelines for determining compliance with a utility credit program to a compliance monitor. The method 711 further includes a step 717 of receiving notification from the compliance monitor regarding the compliance or non-compliance of a utility service customer. The utility service customer is credited at step 719 if the utility service customer is compliant with the utility credit program.

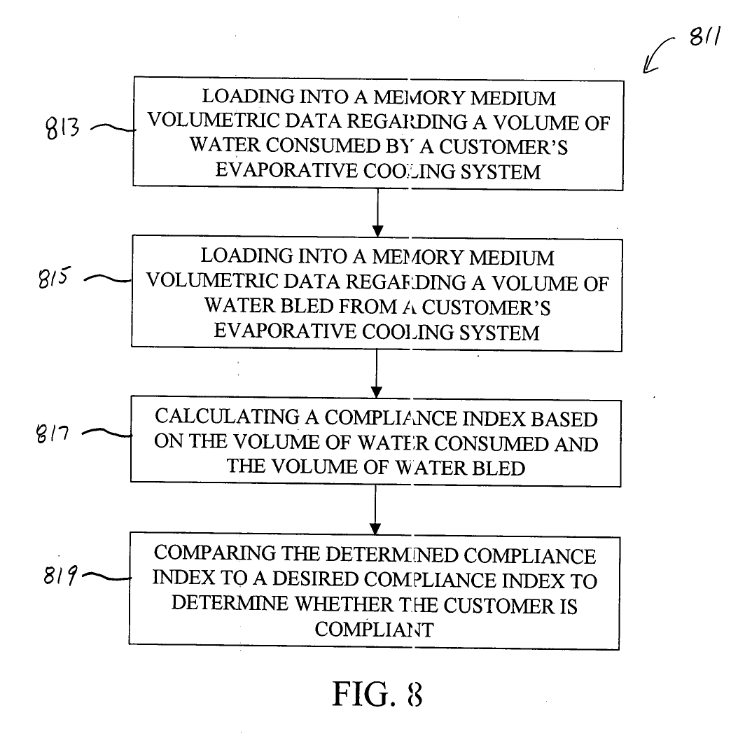

Referring to FIG. 8, a method 811 for monitoring an evaporative credit program according to an embodiment of the present invention includes a step 813 of loading into a memory medium volumetric data regarding a volume of water consumed by a utility service customer's evaporative cooling system. The method 811 further includes a step 815 of loading into a memory medium volumetric data regarding a volume of water bled from the utility service customer's evaporative cooling system. An actual compliance index is calculated at step 817 based on the volume of water consumed by and the volume of water bled from the evaporative cooling system. At step 819, the actual compliance index is compared to a desired compliance index to determine whether the utility service customer is compliant with the evaporative credit program.

In one embodiment, steps 813, 815, 817, and 819 of method 811 may be executed by software 229, 249, and 269 associated with servers 211, 215, and 217 (FIG. 2). The determination of an actual compliance index and the comparison with a desired compliance index may further be performed in accordance with the communication flowcharts illustrated in FIGS. 3 and 4. For example, the determination of an actual compliance index may be accomplished using the following formula:

$$ComlianceIndex = \frac{( VolumeConsumed - VolumedBled )}{VolumeConsumed} , or$$

$$ComlianceIndex = \frac{( VolumeConsumed - VolumedBled )}{VolumedBled} .$$

where VolumeConsumed is the volume of water consumed by the evaporative cooling system during a given time period as indicated by the inflow meter volume, and VolumeBled is the amount of water drained from the evaporative cooling system during the given time period as indicated by the bleed meter volume.

It should be apparent from the foregoing that an invention having significant advantages has been provided. While the invention is shown in only a few of its forms, it is not just limited but is susceptible to various changes and modifications without departing from the spirit thereof.

We claim:

1. An evaporative credit monitoring system comprising:
a compliance server including:
a storage medium storing a desired compliance index; and
a processor operably connected to the storage medium, the processor receiving a water meter reading of a utility service customer and determining an actual compliance index based on the water meter reading, the processor comparing the actual compliance index to the desired compliance index to determine at least one of utility service customer compliance with an evaporative credit program and a conservation opportunity for the utility service customer.

2. The system of claim 1, wherein the storage medium stores the water meter reading received from the utility service customer.

3. The system of claim 1, wherein the water meter reading is received from at least one of a water utility service provider, a municipality, and the utility service customer.

4. The system of claim 1 further comprising a transmission device for reporting whether the utility service customer is compliant to at least one of a water utility service provider and a municipality.

5. The system of claim 1, wherein the desired compliance index is chosen by at least one of a water utility service provider and a municipality.

6. The system of claim 1, wherein the actual compliance index is calculated based on volumetric amounts of water consumed and bled during a given time period.

7. The system of claim 1, wherein the actual compliance index is calculated using the following formula:
$$ComplianceIndex = \frac{VolumeConsumed}{VolumeBled} ,$$
where ComplianceIndex is the actual compliance index, VolumeConsumed is a volumetric amount of water consumed during a given time period, and VolumeBled is a volumetric amount of water bled during the given time period.

8. A method of monitoring an evaporative credit program comprising:
receiving a water meter reading from a utility service customer;
determining an actual compliance index for the utility service customer based on the water meter reading;
comparing the actual compliance index with a desired compliance index to determine at least one of utility service customer compliance with the evaporative credit program and a conservation opportunity tor the utility service customer; and
reporting the at least one of utility service customer compliance and the conservation opportunity for the utility service customer.

9. The method of claim 8 further comprising receiving the desired compliance index from at least one of a water utility service provider and a municipality.

10. The method of claim 8, wherein the water meter reading is received over a network from at least one of a water utility service provider, a municipality, and the utility service customer.

11. The method of claim 8, wherein the water meter reading is received from a wireless meter installed at a cooling tower of the utility service customer.

12. The method of claim 8, wherein customer compliance is reported to at least one of a water utility service provider, a municipality, and the utility service customer.

13. The method of claim 8 further comprising issuing a water utility credit to the utility service customer if the utility service customer is compliant.

14. The method of claim 8 further comprising notifying the utility service customer that the water meter reading has been received.

15. The method of claim 8, wherein determining the actual compliance index further comprises calculating the actual compliance index based on the amount of water consumed and bled during a given time period.

16. The method of claim 8, wherein determining the actual compliance index further comprises calculating the actual compliance index using the following formula:
$$ComplianceIndex = \frac{VolumeConsumed}{VolumeBled} ,$$
where ComplianceIndex is the actual compliance index, VolumeConsumed is a volumetric amount of water consumed during a given time period, and VolumeBled is a volumetric amount of water bled during the given time period.

17. A method of managing an evaporative credit program for a utility service customer having an evaporative cooling system, the method comprising:
communicating to a compliance monitor guidelines for determining compliance with a utility credit program;
receiving notification from the compliance monitor regarding the compliance or non-compliance of the utility service customer; and
crediting the utility service customer if the utility service customer is compliant with the utility credit program.

18. The method of claim 17, wherein the notification regarding compliance is received over a network.

19. The method of claim 17, wherein the utility service customer is credited by sending an invoice with the credit to the utility service customer.

20. The method of claim 17, wherein compliance is determined by the compliance monitor by calculating an actual compliance index based on the amount of water consumed and bled by the evaporative cooling system during a given time period.

21. The method of claim 17, wherein compliance is determined by the compliance monitor by calculating an actual compliance index using the following formula:
$$ComplianceIndex = \frac{VolumeConsumed}{VolumeBled} ,$$
where ComplianceIndex is the compliance index, VolumeConsumed is a volumetric amount of water consumed by the cooling tower during a given time period, and VolumeBled is a volumetric amount of water bled by the evaporative cooling system during the given time period.

22. In an electronic system, in which at least one computer monitors an evaporation credit program for a utility service customer having an evaporative cooling system, a memory medium having software programmed to:
receive a water meter reading from the utility service customer;
determine an actual compliance index for the utility service customer based on the water meter reading;
compare the actual compliance index with a desired compliance index to determine whether the utility service customer is compliant or non-compliant; and
report whether the utility service customer is compliant or non-compliant with the evaporative credit program.

23. The system of claim 22, wherein the software is further programmed to receive the desired compliance index from at least one of a water utility service provider and a municipality.

24. The system of claim 22, wherein the software is further programmed to receive the water meter reading over a network from at least one of a water utility service provider, a municipality, and the utility service customer.

25. The system of claim 22, wherein the software is further programmed to receive the water meter reading from a wireless meter installed at the evaporative cooling system of the utility service customer.

26. The system of claim 22, wherein the software is further programmed to report customer compliance to at least one of a water utility service provider, a municipality, and the utility service customer.

27. The system of claim 22, wherein the software is further programmed to issue a water utility credit to the utility service customer if the utility service customer is compliant.

28. The system of claim 22, wherein the software is further programmed to notify the utility service customer that the water meter reading has been received.

29. The system of claim 22, wherein the software is further programmed to determine the actual compliance index by calculating the actual compliance index based on the amount of water consumed and bled during a given time period.

30. The system of claim 22, wherein the software is further programmed to determine the actual compliance index by calculating the actual compliance index using the following formula:
$$ComplianceIndex = \frac{VolumeConsumed}{VolumeBled} ,$$
where ComplianceIndex is the actual compliance index, VolumeConsumed is a volumetric amount of water consumed during a given time period, and VolumeBled is a volumetric amount of water bled during the given time period.

31. At least one computer programmed to execute a process for monitoring an evaporation credit program for a utility service customer having an evaporative cooling system, the process comprising:
receiving a water meter reading from the utility service customer;
determining an actual compliance index for the utility service customer based on the water meter reading;
comparing the actual compliance index with a desired compliance index to determine whether the utility service customer is compliant or non-compliant; and
reporting whether the utility service customer is compliant or non-compliant with the evaporative credit program.

32. The computer of claim 31, wherein the process further comprises receiving the desired compliance index from at least one of a water utility service provider and a municipality.

33. The computer of claim 31, wherein the water meter reading is received over a network from at least one of a water utility service provider, a municipality, and the utility service customer.

34. The computer of claim 31, wherein the water meter reading is received from a wireless meter installed at the evaporative cooling system of the utility service customer.

35. The computer of claim 31, wherein customer compliance is reported to at least one of a water utility service provider, a municipality, and the utility service customer.

36. The computer of claim 31, wherein the process further comprises issuing a water utility credit to the utility service customer if the utility service customer is compliant.

37. The computer of claim 31, wherein the process further comprises notifying the utility service customer that the water meter reading has been received.

38. The computer of claim 31, wherein determining the actual compliance index further comprises calculating the actual compliance index based on the amount of water consumed and bled during a given time period.

39. The computer of claim 31, wherein determining the actual compliance index further comprises calculating the actual compliance index using the following formula:
$$ComplianceIndex = \frac{VolumeConsumed}{VolumeBled} ,$$
where ComplianceIndex is the actual compliance index, VolumeConsumed is a volumetric amount of water consumed during a given time period, and VolumeBled is a volumetric amount of water bled during the given time period.

40. A method of monitoring an evaporative credit program comprising:
receiving a water meter reading from a utility service customer;
determining evaporation data based on the water meter reading;
communicating the evaporation data to a utility service provider to obtain an evaporation credit for the utility service customer, the evaporation credit resulting in a monetary savings to the utility service customer; and
receiving payment from the utility service customer in return for the monetary savings obtained by the utility service customer.

41. The method of claim 40, wherein the water meter reading is received over a network from at least one of the utility service provider, a municipality, and the utility service customer.

42. The method of claim 40, wherein the water meter reading is received from a wireless meter installed at an evaporative cooling system of the utility service customer.

43. The method of claim 40 further comprising determining an actual compliance index for the utility service customer based on the water meter reading.

44. The method of claim 43, wherein determining the actual compliance index further comprises calculating the actual compliance index using the following formula:
$$ComplianceIndex = \frac{VolumeConsumed}{VolumeBled} ,$$
where ComplianceIndex is the actual compliance index, VolumeConsumed is a volumetric amount of water consumed during a given time period, and VolumeBled is a volumetric amount of water bled during the given time period.

45. The method of claim 40, wherein the payment from the utility service customer is at least one of a fixed fee and a percentage of the monetary savings obtained by the utility service customer.
